(19) United States
(12) Patent Application Publication
(10) Pub. No.: US 2025/0079800 A1
(43) Pub. Date: Mar. 6, 2025

(54) VERTICAL-CAVITY SURFACE-EMITTING LASER WITH A PLANAR SURFACE OXIDIZED GRATING

(71) Applicant: Lumentum Operations LLC, San Jose, CA (US)

(72) Inventors: Eric R. HEGBLOM, Sunnyvale, CA (US); Richa DUBEY, Milpitas, CA (US); Benjamin KESLER, Livemore, CA (US)

(21) Appl. No.: 18/545,914

(22) Filed: Dec. 19, 2023

Related U.S. Application Data
(60) Provisional application No. 63/579,366, filed on Aug. 29, 2023.

(51) Int. Cl. H01S 5/183

(52) U.S. Cl. CPC H01S 5/18377

(57) ABSTRACT

A vertical-cavity surface-emitting laser (VCSEL) may include a first top mirror structure over a cavity region. The VCSEL may include a grating layer over the first top mirror structure. The grating layer may comprise a plurality of oxidized regions that form a grating structure in the grating layer. The grating structure may be associated with polarization of output light emitted by the VCSEL. The surface of the grating layer may be a planar surface.

### CROSS-REFERENCE TO RELATED APPLICATION

This patent application claims priority to U.S. Provisional Patent Application No. 63/579,366, filed on Aug. 29, 2023, and entitled “VERTICAL-CAVITY SURFACE-EMITTING LASER WITH A PLANAR SURFACE OXIDIZED GRATING.” The disclosure of the prior Application is considered part of and is incorporated by reference into this Patent Application.

### TECHNICAL FIELD

The present disclosure relates generally to a vertical-cavity surface-emitting laser (VCSEL) and to a VCSEL comprising a planar surface oxidized grating.

### BACKGROUND

A VCSEL is a semiconductor laser, more specifically a diode laser with a monolithic laser resonator, where light is emitted in a direction perpendicular to a chip surface. Typically, the laser resonator consists of two distributed Bragg reflector (DBR) mirror structures parallel to a chip surface, between which is a cavity region (consisting of one or more quantum wells) that generates light. The upper and lower mirror structures of a VCSEL are doped to form a diode junction by, for example, p-doping the upper mirror structure of the VCSEL and n-doping the lower mirror structure of the VCSEL.

### SUMMARY

In some implementations, a VCSEL includes a first top mirror structure over a cavity region; and a grating layer over the first top mirror structure, wherein the grating layer comprises a plurality of oxidized regions that form a grating structure in the grating layer, the grating structure being associated with polarization of output light emitted by the VCSEL, and wherein the surface of the grating layer is a planar surface.

In some implementations, a VCSEL includes a mirror structure over a cavity region; and a grating layer over the mirror structure, wherein the grating layer comprises a plurality of oxidized regions that define a grating structure, and wherein a top surface of the grating layer is substantially planar.

In some implementations, a VCSEL includes a first top mirror structure over a cavity region; and a planar grating layer over the first top mirror structure, wherein the planar grating layer comprises a plurality of oxidized regions that form a grating structure within the grating layer, and wherein the grating structure is associated with increasing reflectivity on a side of the VCSEL that includes the first top mirror structure.

### BRIEF DESCRIPTION OF THE DRAWINGS

FIGS. 1A and 1B are diagrams associated with an example implementation of a VCSEL including a planar surface oxidized grating as described herein.

FIGS. 2A-2C are diagrams illustrating examples of process steps associated with forming a grating structure in a grating layer of the VCSEL described herein.

FIG. 3 is a diagram illustrating an alternative implementation of a VCSEL including a planar surface oxidized grating as described herein.

FIGS. 4A and 4B are diagrams illustrating a comparison of oxidation profiles for different gradings of aluminum with a grating layer of the VCSEL described herein.

### DETAILED DESCRIPTION

The following detailed description of example implementations refers to the accompanying drawings. The same reference numbers in different drawings may identify the same or similar elements.

Conventionally, a grating is formed on a VCSEL by either etching into an epitaxial surface or depositing additional material (e.g., a dielectric or a metal) and then etching the added material. However, such techniques inevitably result in a non-planar surface at the grating. In an application in which the grating is not the final surface (i.e., when one or more other materials are to be deposited over the grating), the non-planar surface is problematic. One example, in which the grating is not the final surface, is a bottom-emitting VCSEL. Ideally, materials formed over the grating need to cover the grating in a consistent manner, ideally planarizing the surface. For a bottom-emitting VCSEL, the need to have additional reflectivity above the grating is critical because the top reflector of a bottom-emitting VCSEL needs to be very high. If a grating (e.g., for polarization control) is placed at the top of a highly reflective mirror (e.g., a mirror with at least 99.7% reflectivity), then an influence of the grating on a lasing mode will be low and not effective to influence the polarization or other modal properties. In order for the grating to be effective, the grating needs to be closer to an active region of the VCSEL, and additional mirror pairs are needed above the grating to minimize loss of light out of the top of the bottom-emitting VCSEL.

Conventional techniques to achieve consistent coverage of such an etched grating structure are very difficult. For example, a film deposited by physical or chemical vapor deposition may leave voids or bumps inconsistently (e.g., across a wafer or run-to-run) over the grating. Further, a spin-on film, such as a polyimide, or a spin-on glass generally does not have a tightly controlled thickness, which is needed in the case of a VCSEL. Notably, such a film may have a planar surface, but if the viscosity of the film is high, then the film will not fill in the grating and leaves inconsistent voids. Additionally, a soft material such as a film may also have problems adhering to the surface of the grating.

Some implementations described herein provide a VCSEL comprising a planar surface oxidized grating. In some implementations, the VCSEL includes a first top mirror structure over a cavity region, and a grating layer over the first top mirror structure. In some implementations, the grating layer comprises a plurality of oxidized regions that form a grating structure in the grating layer, with the surface of the grating layer being a planar surface. Thus, in some implementations, the VCSEL includes a surface grating formed by oxidation of the underlying material (i.e., the grating layer), which results in a substantially planar surface.

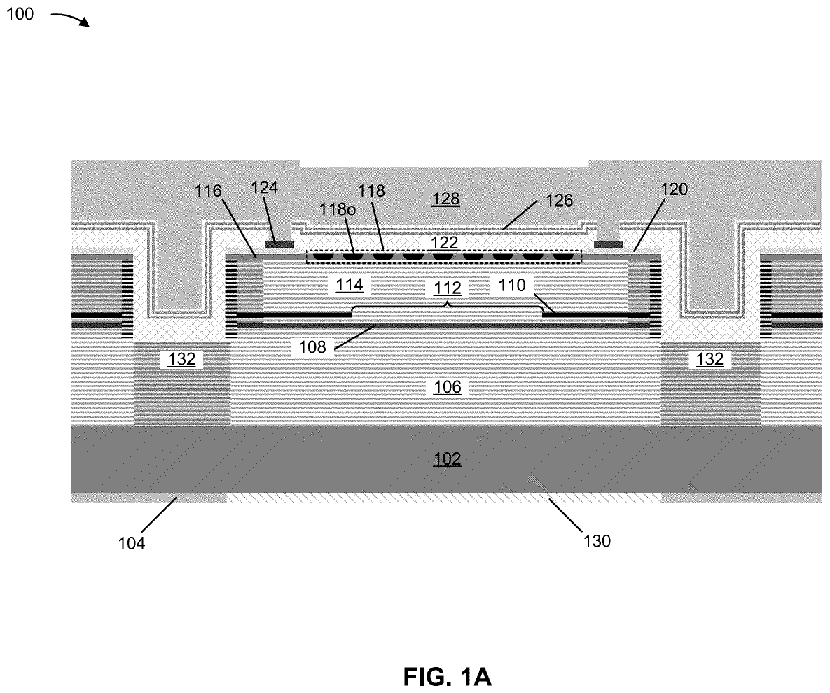

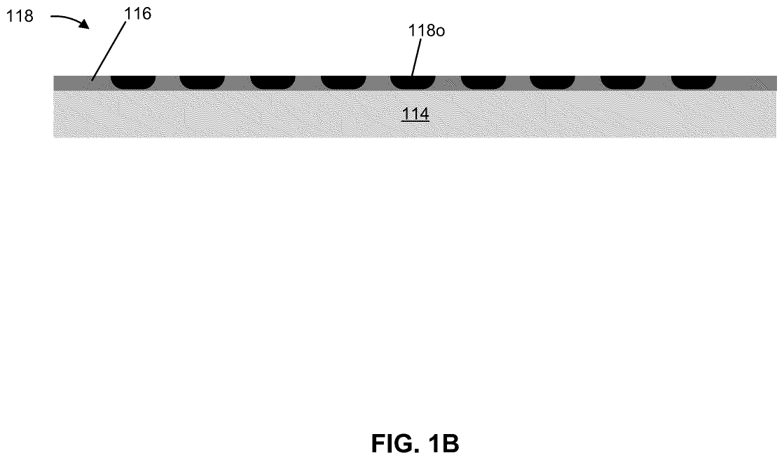

FIGS. 1A and 1B are diagrams associated with an example implementation of a VCSEL 100 including a planar surface oxidized grating as described herein. In some implementations, the VCSEL 100 may be included in an array of emitters (e.g., an array of VCSELs 100). In some implementations, as illustrated in FIG. 1A, the VCSEL 100 is a bottom-emitting VCSEL (also referred to as a backside emitting (BSE) VCSEL), meaning that the VCSEL 100 emits light through the substrate 102 of the VCSEL 100. In some implementations, the VCSEL 100 may be a single mode VCSEL. Alternatively, the VCSEL 100 may be a multi-mode VCSEL.

As shown in FIG. 1A, the VCSEL 100 may include a substrate 102, a bottom metal 104, a bottom mirror structure 106, a cavity including one or more active regions (herein referred to as cavity region(s) 108), a confinement layer 110 that forms a confinement aperture 112, a first top mirror structure 114, a grating layer 116 including a grating structure 118 comprising a plurality of oxidized regions 1180, a cap layer 120, a dielectric layer 122, a contact layer 124, a second top mirror structure 126, a top metal 128, and one or more isolation implants 132.

Substrate 102 includes a supporting material upon which, or within which, one or more layers or features of the VCSEL 100 are grown or fabricated. In some implementations, the substrate 102 comprises an n-type material. In some implementations, the substrate 102 comprises a semi-insulating type of material. In some implementations, when the VCSEL 100 includes one or more bottom-emitting emitters, the semi-insulating type of material may be used to reduce optical absorption from the substrate 102. In such an implementation, the VCSEL 100 may include a contact buffer in or near the bottom mirror structure 106. In some implementations, the substrate 102 may include a semiconductor material, such as gallium arsenide (GaAs), indium phosphide (InP), or another type of semiconductor material. In some implementations, a bottom contact (e.g., a bottom n-contact) of the VCSEL 100 can be made from a backside of the substrate 102. In some implementations, the bottom contact of the VCSEL 100 can be made from a front side of the VCSEL 100. In some implementations, the front side contact can be achieved by, for example, etching a mesa step or trench to the substrate 102, or inserting a contact buffer in or near the bottom mirror structure 106.

Bottom metal 104 includes a metal layer on a bottom surface of the substrate 102 (e.g., at a backside of the VCSEL 100). In some implementations, the bottom metal 104 is an ohmic metal layer. In some implementations, the bottom metal 104 is formed on an n-type semiconductor substrate 102 or an n-type semiconductor layer in the bottom mirror structure 106. Alternatively, the bottom metal 104 may in some implementations be formed from on a p-type semiconductor substrate 104 or a p-type semiconductor layer in the bottom mirror structure 106. In some implementations, the bottom metal 104 is a layer that makes electrical contact with the substrate 102. In some implementations, the bottom metal 104 serves as an anode for the VCSEL 100. Alternatively, the bottom metal 104 may in some implementations serve as a cathode for the VCSEL 100. In some implementations, the bottom metal 104 may include an annealed metallization layer, such as a gold-germanium-nickel (AuGeNi) layer, or a palladium-germanium-gold (PdGcAu) layer, among other examples. In some implementations, as shown in FIG. 1A, an anti-reflective (AR) coating 130 may be formed in an opening in the bottom metal 104 (e.g., an opening through which the VCSEL 100 is to emit light).

Bottom mirror structure 106 is a bottom reflector of an optical resonator of the VCSEL 100. For example, the bottom mirror structure 106 may include a plurality of distributed Bragg reflector (DBR) pairs, or another type of mirror structure. In some implementations, the bottom mirror structure 106 is formed from an n-type material. Thus, in some implementations, the bottom mirror structure 106 may include a plurality of n-type DBR pairs. Alternatively, the bottom mirror structure 106 may in some implementations be formed from a p-type material. In some implementations, the bottom mirror structure 106 is on a (top) surface of the substrate 102. In some implementations, the bottom mirror structure 106 may have a thickness in a range from approximately 2.5 micrometers (μm) to approximately 9 μm, such as 5 μm. In some implementations, the bottom mirror structure 106 includes a set of layers (e.g., aluminum gallium arsenide (AlGaAs) layers) grown using a metal-organic chemical vapor deposition (MOCVD) technique, a molecular beam epitaxy (MBE) technique, or another technique.

Cavity region 108 includes one or more layers where electrons and holes recombine to emit light and define the emission wavelength range of the VCSEL 100. For example, the cavity region 108 may include one or more active regions in the form of one or more quantum wells (QWs). In some implementations, the cavity region 108 may include one or more cavity spacer layers (e.g., to enable epitaxial growth to have sufficient room for ramping compositions or temperature). In some implementations, the one or more cavity spacer layers may reduce strain between active regions of the cavity region 108 and/or may mitigate thermal issues of laser operation of the VCSEL 100. In some implementations, the one or more cavity spacer layers may include an oxidation layer. An optical thickness of the cavity region 108 (including the one or more active regions and any cavity spacer layers), the first top mirror structure 114, the second top mirror structure 126, and the bottom mirror structure 106 may define a resonant cavity wavelength of the VCSEL 100, which may be designed within an emission wavelength range of the cavity region 108 to enable lasing. The wavelength range of the VCSEL 100 may in some implementations be in a range from approximately 800 nanometers (nm) to approximately 1550 nm. In some implementations, the cavity region 108 may be formed on the bottom mirror structure 106. In some implementations, the cavity region 108 may have a thickness of a positive integer multiple of half wavelengths typically between 0.1 μm and 1.5 μm, such as 0.3 μm. In some implementations, the cavity region 108 includes a set of layers grown using an MOCVD technique, an MBE technique, or another technique.

Confinement layer 110 comprises one or more layers that provide optical and/or electrical confinement for the VCSEL 100. In some implementations, the confinement layer 110 enhances carrier and mode confinement of the VCSEL 100 and, therefore, can improve performance of the VCSEL 100. In some implementations, the confinement layer 110 is on, under, or in the cavity region 108. In some implementations, there may be one or more spacer layers or mirror layers (e.g., DBRs) between the confinement layer 110 and the cavity region 108. In some implementations, as shown in FIG. 1A, the confinement layer 110 is on a side of the cavity region 108 nearer to the first top mirror structure 114 (i.e., on a non-substrate side of the cavity region 108). In some implementations, the confinement layer 110 is on a side of the cavity region 108 nearer to the bottom mirror structure 106 (i.e., on a substrate side of the cavity region 108).

In some implementations, the confinement layer 110 comprises an oxide layer formed by oxidation of one or more epitaxial layers of the VCSEL 100. For example, the confinement layer 110 may be an aluminum oxide (Al₂O₃) layer formed as a result of oxidation of an epitaxial layer (e.g., an AlGaAs layer, an AlAs layer, and/or the like). In some implementations, the confinement layer 110 may have a thickness in a range from approximately 0.007 μm to approximately 0.04 μm, such as 0.02 μm. In some implementations, oxidation trenches etched around the VCSEL 100 (shown as filled in FIG. 1A) may allow steam to access the epitaxial layer(s) from which the confinement layer 110 is formed. In some implementations, the oxidation trenches may not fully enclose the confinement layer 110. For example, the oxidation trenches may follow the general shape of the confinement region, but there may be gaps between adjacent oxidation trenches. In some implementations, the confinement layer 110 may follow the general geometric shape, but may have variations associated with shapes or locations of the oxidation trenches and/or variations associated with an oxidation rate. In some implementations, in addition to the confinement layer 110, the VCSEL 100 may include one or more other types of structures or layers that provide current confinement, such as an implant passivation structure, a mesa isolation structure, a moat trench isolation structure, a buried tunnel junction, or the like. Additionally, or alternatively, other types of structures or layers for providing current confinement may be included in or integrated with the confinement layer 110.

In some implementations, the confinement layer 110 defines the confinement aperture 112. Thus, in some implementations, the confinement aperture 112 is an optically active aperture defined by the confinement layer 110. In some implementations, a size (e.g., a width in a given direction) of the confinement aperture 112 is in a range from approximately 1 μm to approximately 300 μm, such as 5 μm or 8 μm. In some implementations, as described above, the confinement aperture 112 may be formed by oxidation (e.g., when the confinement layer 110 is an oxidized layer). Additionally, or alternatively, the confinement aperture 112 may be formed by other means, such as by implantation, diffusion, regrowth (e.g., using a high resistance layer, a current blocking layer, a tunnel junction, or the like), or an air gap, among other examples. In some implementations, the confinement layer 110 may define multiple confinement apertures 112 (e.g., such that the VCSEL 100 comprises multiple confinement apertures). In such an implementation, sizes of the multiple confinement apertures may vary (e.g., as defined by oxidation among layers of the confinement layer 110).

First top mirror structure 114 is a top reflector of the optical resonator of the VCSEL 100. For example, the first top mirror structure 114 may include a plurality of DBR pairs, or another type of mirror structure. In some implementations, the first top mirror structure 114 is formed from a p-type material. Thus, in some implementations, the first top mirror structure 114 comprises a plurality of p-type DBR pairs. Alternatively, the first top mirror structure 114 may in some implementations be formed from an n-type material. In some implementations, the first top mirror structure 114 may have a thickness in a range from approximately 1 μm to approximately 4 μm, such as 2 μm. In some implementations, the first top mirror structure 114 includes a set of layers (e.g., AlGaAs layers) grown using an MOCVD technique, an MBE technique, or another technique. In some implementations, the first top mirror structure 114 is grown on or over the cavity region 108.

Grating layer 116 is a layer comprising the grating structure 118. In some implementations, the grating structure 118 may be associated with polarization of light emitted by the VCSEL 100. For example, the grating structure 118 may introduce a polarization dependence to reflectivity of the VCSEL 100, an effect of which is suppression of one of the two orthogonal polarization orientations of the light (e.g., such that the light emitted by the VCSEL 100 has a single polarization orientation). Additionally, or alternatively, the grating structure 118 may be associated with increasing reflectivity on a side of the VCSEL 100 that includes the first top mirror structure 114. In some implementations, the grating structure 118 has a grating depth and a grating period that are on an order of or lower than a wavelength of the VCSEL 100. In some implementations, as shown in FIG. 1A, the grating structure 118 is defined by a plurality of oxidized regions 1180.

In some implementations, the grating layer 116 comprises an AlGaAs layer. In some implementations, a thickness of the grating layer 116 may be in a range from approximately 0.11×λ to approximately 0.26×λ., where λ is a wavelength of the VCSEL 100. In one example, for a 940 nm wavelength (λ=940 nm), the thickness of the grating layer 116 may be in a range from approximately 100 nm to approximately 250 nm. In some implementations, an aluminum content of the grating layer 116 may be in a range from approximately 20% to approximately 100%. More particularly, in some implementations, the aluminum content of the grating layer 116 may be in a range from 50% to approximately 80%, such as 75%. In some implementations, oxidation of AlGaAs produces a material with a refractive index of approximately 1.6, which is good contrast to neighboring AlGaAs, which has a refractive index in a range from approximately 3.0 to approximately 3.4 (e.g., depending upon composition and wavelength).

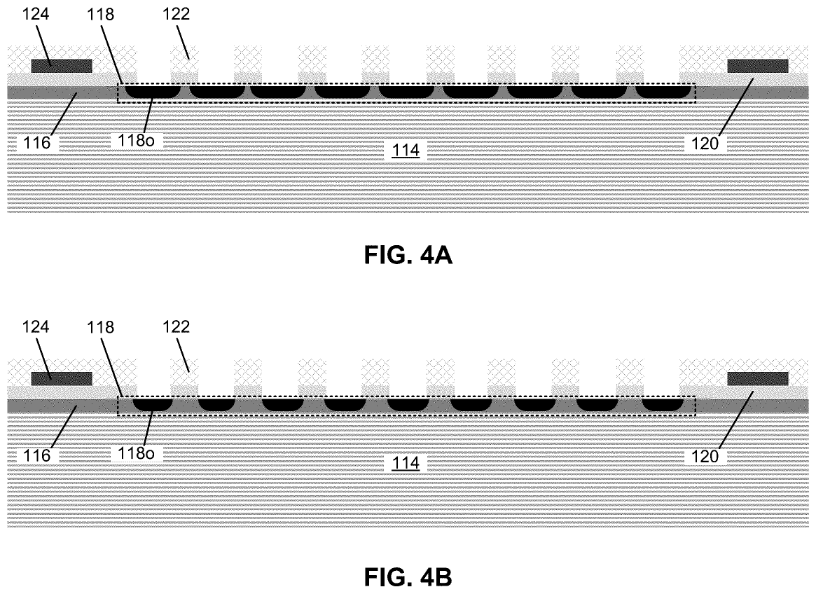

In some implementations, an aluminum composition within the grating layer 116 may be uniform across a thickness of the grating layer 116 (e.g., a vertical direction in FIG. 1A). Alternatively, the aluminum composition within the grating layer may in some implementations be graded across the thickness of the grating layer 116. In some implementations, the grading of the aluminum content of the grating layer 116 can be selected so as to control an oxidation profile of the grating layer 116, as described in further detail below with respect to FIGS. 4A and 4B.

FIG. 1B is a diagram illustrating an example of the grating structure 118 defined by the plurality of oxidized regions 1180. As shown in FIG. 1B, in some implementations, the plurality of oxidized regions 1180 that define the grating structure 118 are planar with the surface of the grating layer 116. That is, selective surface oxidation on an epitaxial structure—the grating layer 116—can be used to form a grating (or photonic crystal structure) that is inherently planar. Such a grating structure 118 may be referred to as a planar surface oxidized grating. The grating structure 118 may have a pattern that comprises, for example, a series of lines (e.g., from a top view of the VCSEL 100), or may be another type of pattern, such as an array of dots like a photonic crystal structure.

In some implementations, as illustrated in FIG. 1B, a width of a given oxidized region 1180 may be greater than a depth of the given oxidized region 1180. In some implementations, a depth of a given oxidized region 1180 may be in a range from approximately 0.11×λ to approximately 0.26×λ, where λ is a wavelength of the VCSEL 100. In one example, for a 940 nm wavelength (λ=940 nm), a depth of a given oxidized region 1180 may be in a range from approximately 100 nm to approximately 250 nm, such as 125 nm. In some implementations, a width of a given oxidized region 1180 may be equal to a pitch p of the pattern of the grating structure times one minus a duty cycle DC of the pattern (width=p×(1−DC)). In some implementations, the duty cycle DC may be in a range from approximately 0.4 to approximately 0.6, such as 0.5. As one example, for a duty cycle DC of 0.5 and a pitch p in a range from 0.20 μm to 0.45 μm, the width of a given oxidized region 1180 may be in a range from approximately 0.11×λ to approximately 0.24×λ. In one example, for a 940 nm wavelength (λ=940 nm), a width of a given oxidized region 1180 may be in a range from approximately 0.10 μm to approximately 0.23 μm for a duty cycle DC of 0.5. In some implementations, a pitch of the pattern of the grating structure 118 may be in a range from approximately 0.20 μm to approximately 0.45 μm. Additionally, or alternatively, the pitch of the pattern may be in a range from approximately 0.21×λ to approximately 0.48×λ, where λ is a wavelength of the VCSEL 100.

Returning to FIG. 1A, the cap layer 120 is a layer associated with capping or protecting one or more layers or features of the VCSEL. For example, the cap layer 120 may serve to protect some portions of the grating layer 116 (e.g., portions of the grating layer 116 in which oxidized regions are not to be formed) from oxidation. In some implementations, as shown in FIG. 1A, the cap layer 120 is over the first top mirror structure 114. In some implementations, as illustrated in FIG. 1A, the cap layer 120 is over regions of the grating layer 116 in which the grating structure 118 is not present. In some implementations, the cap layer 120 comprises a semiconductor material, such as GaAs (e.g., highly doped GaAs). In some implementations, the cap layer 118 has a thickness in a range from approximately 0.02 μm to approximately 0.05 μm, such as 0.04 μm.

Dielectric layer 122 is a layer that at least partially insulates the top metal 128 from one or more other layers or features (e.g., sidewalls of trenches). Further, the dielectric layer 122 may serve to protect the grating layer 116. In some implementations, the dielectric layer 122 may comprise, for example, silicon nitride (SiN_{X}), silicon dioxide (SiO₂), a polymer dielectric, or another type of insulating material. In some implementations, a first portion of the dielectric 122 may be formed prior to formation of the plurality of oxidized regions 1180, and a second portion of the dielectric layer 122 may be formed after the formation of the plurality of oxidized regions 1180. In some implementations, the dielectric layer 122 may have a thickness t in a range from approximately 0.92×(λ/n_{d}) and approximately 1.45×(λ/n_{d}), where λ is the wavelength of the VCSEL 100 and n_{d} is a refractive index of the dielectric material. More generally, the dielectric layer 122 may have a thickness T that is equal to the thickness t plus or minus a value corresponding to a multiple of the wavelength of the VCSEL 100 divided by two times the refractive index of the dielectric material equal (e.g., T=t±X×λ/(2*n_{d}), where 0.92×(λ/n_{d})≤1≤1.45×(λ/n_{d}) and X is an integer value such as 0, 1, 2, or the like. In some implementations, the thickness T of the dielectric layer 122 may vary by some amount (e.g., +10 nm, +15 nm) depending on VCSEL design. Thus, in some implementations, the dielectric layer 122 has a thickness that is within approximately 15 nm of a value equal to a value in a range from approximately 0.92×(λ/n_{d}) and approximately 1.45×(λ/n_{d}) plus or minus a value equal to Xx λ/(2*n_{d}), where λ is the wavelength of the VCSEL, n_{d} is a refractive index of a dielectric material, and X is an integer value.

Top contact layer 124 is a top contact layer of the VCSEL 100 that makes electrical contact with the first top mirror structure 114 through which current may flow. In some implementations, the top contact layer 124 is formed from materials optimized for contacting a p-type semiconductor. Alternatively, the contact layer 124 is in some implementations formed from materials optimized for contacting an n-type semiconductor. In some implementations, the top contact layer 124 has a thickness in a range from approximately 0.2 μm to approximately 0.8 μm, such as 0.5 μm. In some implementations, the top contact layer 124 has a ring shape, a slotted ring shape, a tooth wheel shape, or another type of circular or non-circular shape (e.g., depending on a design of the VCSEL 100). In some implementations, in the case of a non-circular shape, axes of the non-circular shape may be perpendicular to or parallel to a direction of a given oxidized region 1180.

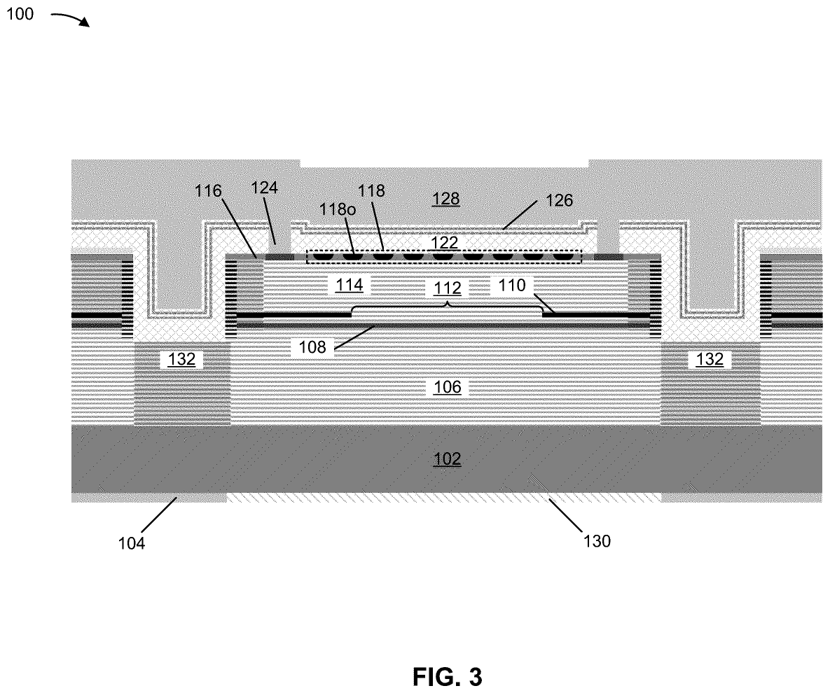

In some implementations, as shown in FIG. 1A, the top contact layer 124 is over the grating layer 116 (e.g., on the cap layer 120). Alternatively, the top contact layer 124 may in some implementations be under the grating layer 116. Alternatively, the top contact layer 124 may in some implementations be in an opening in the grating layer 116 (e.g., an example of which is illustrated in FIG. 3 described below).

Second top mirror structure 126 is a top reflector of the optical resonator of the VCSEL 100. In some implementations, the second top mirror structure 126 is configured to increase reflectivity on the side of the VCSEL 100 that includes the first top mirror structure 114 (e.g., the top side of the VCSEL 100). Without top mirror structure 126, integration of an optical element, such as a grating, in a BSE VCSEL on top of an all-semiconductor DBR mirror is less effective (e.g., as compared to top emitting VCSELs) because of the high reflectivity required and the reduced interaction of cavity modes with the optical element. Reducing a quantity of mirror pairs in a top mirror structure increases coupling of the cavity modes with such an optical element. However, reducing the quantity of mirror pairs in the top mirror structure reduces reflectivity in the side of the VCSEL comprising the top mirror structure. In VCSEL 100, the second top mirror structure 126 serves to increase reflectivity in the side of the VCSEL 100 including the first top mirror structure 114. Therefore, the quantity of mirror pairs in the first top mirror structure 114 can be reduced, and the second top mirror structure 126 can be designed to mitigate the reduction in reflectivity caused by the decrease in the quantity of mirror pairs in the first top mirror structure 114. In some implementations, the second top mirror structure 126 may include a plurality of DBR pairs, or another type of mirror structure. In some implementations, the second top mirror structure 126 is formed from a dielectric material. Thus, in some implementations, the second top mirror structure 126 comprises a plurality of dielectric DBR pairs. For example, the second top mirror structure 126 may comprise a plurality of SiO₂/SiNx mirror pairs, a plurality of SiO₂/titanium dioxide (TiO₂) mirror pairs, or a plurality of Al₂O₃/TiO₂ mirror pairs, among other examples. In some implementations, the second top mirror structure 126 may have a thickness in a range from approximately 2.0 μm to approximately 4.0 μm, such as 2.5 μm. In some implementations, a quantity of mirror pairs in the second top mirror structure 126 is in a range from three mirror pairs to eight mirror pairs.

The top metal 128 is a top metal layer at a front side of the VCSEL 100. In some implementations, the top metal 128 may be a layer that makes electrical contact with the top contact layer 124 (e.g., through vias in the dielectric layer 122 and the second top mirror structure 126). In some implementations, the top metal 128 may serve as a cathode for the VCSEL 100. In some implementations, the top metal 128 may comprise a plating metal (e.g., a gold (Au)) and/or a seed metal used in the plating process.

Isolation implant 132 is a region to prevent free carriers from reaching edges of trenches and/or to isolate adjacent VCSELs 100 from one another (e.g., if the trenches do not fully enclose the VCSELs of the VCSEL 100). Isolation implant 132 may comprise, for example, an ion implanted material, such as a hydrogen/proton implanted material or a similar implanted element to reduce conductivity.

The number, arrangement, thicknesses, order, symmetry, or the like, of layers shown in FIGS. 1A and 1B are provided as examples. In practice, the VCSEL 100 may include additional layers, fewer layers, different layers, differently constructed layers, or differently arranged layers than those shown in FIGS. 1A and 1B. For example, in some implementations, the VCSEL 100 may comprise a semiconductor layer (e.g., one or more p-type layers) over the grating layer 116 (e.g., rather than the dielectric 122). As another example, in some implementations, the VCSEL may comprise an air interface over the grating layer 116 (e.g., rather than the dielectric layer 122 and the top metal 128). Additionally, or alternatively, a set of layers (e.g., one or more layers) of the VCSEL 100 may perform one or more functions described as being performed by another set of layers of the VCSEL 100, and any layer may comprise more than one layer.

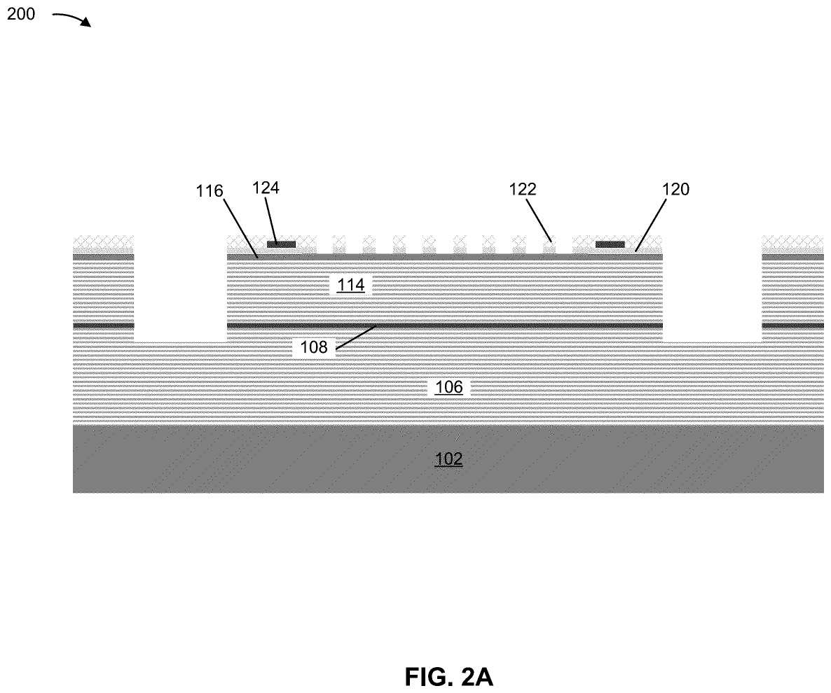

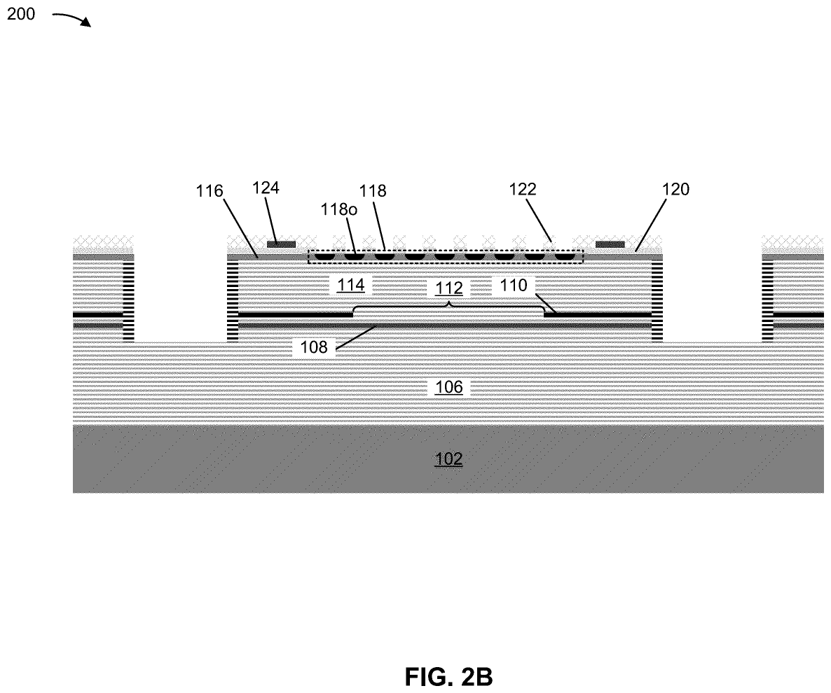

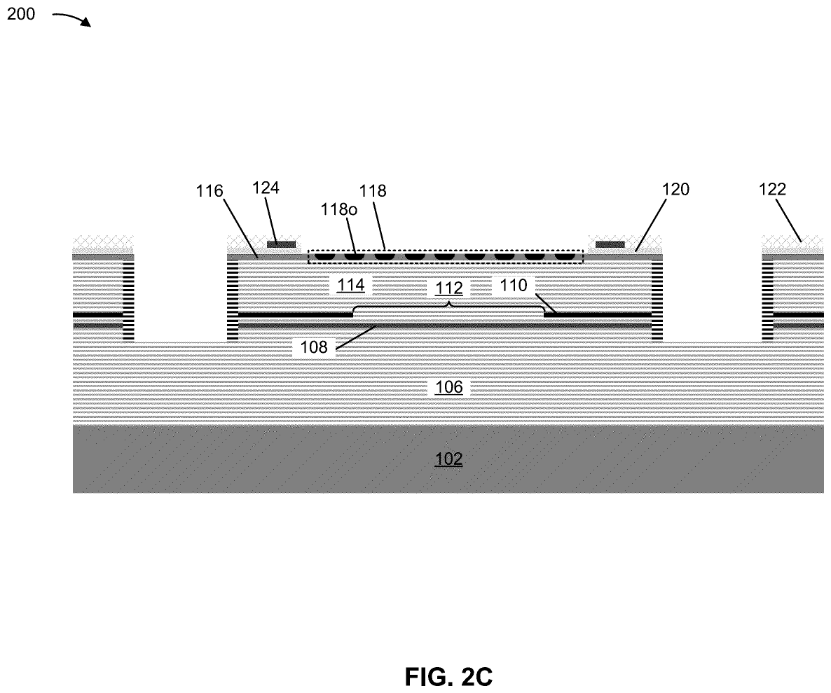

In some implementations, to form the grating structure 118, epitaxial layers are grown (as a single step) and then a grating pattern is etched into sacrificial layers above the grating layer 116 to expose portions of the grating layer 116. The grating layer 116 is then oxidized to form the plurality of oxidized regions 1180. After oxidation, the sacrificial layers are removed, leaving the grating structure 118 in the grating layer 116, while maintaining a substantially planar surface (e.g., as compared to an etched grating). FIGS. 2A-2C are diagrams illustrating examples 200 of such process steps associated with forming the grating structure 118 in grating layer 116 of the VCSEL 100.

In the example shown in FIG. 2A, a portion of the dielectric layer 122 (e.g., SiNx) is deposited after the formation of the semiconductor epitaxial layers, and the portion of the dielectric layer 122 is patterned and etched along with the cap layer 120 (in the same pattern) to expose portions of the grating layer 116. Here, the grating layer 116 has a higher aluminum content AlₓGa₁₋ₓAs than a layer beneath the grating layer 116. In some implementations, selective wet etching or dry etching can be used to stop the etch on the higher aluminum content grating layer 116. FIG. 2A shows a result of the patterning and etching associated with forming the grating structure, as well as etching of (deeper) oxide trenches around the VCSEL 100 (which may be done as a step after the high resolution patterning of the surface). In some implementations, the aluminum content in the AlGaAs grating layer 116 need not be very high because only a shallow surface oxidation is required. For example, as noted above, a mole fraction (x) in a range from approximately 50% to approximately 80% aluminum may be used. In some implementations, the mole fraction may be lower (e.g., as low as 20%) or higher (e.g., up to 100%).

In a next step, as illustrated in FIG. 2B, the exposed portions of the surface of the AlGaAs grating layer 116 are oxidized to form the plurality of oxidized regions 1180 that define the grating structure 118. As shown, the confinement layer 110 can also be formed during this process step.

In a next step, as illustrated in FIG. 2C, remaining portions of the layers above the grating structure 118 can removed by selective etching, with this selective etching being stopped at the higher aluminum content AlGaAs grating layer 116. One or more other layers can be subsequently formed over the grating layer 116. The one or more other layers may include, for example, another portion of the dielectric layer 122, and/or the second top mirror structure 126 (e.g., to enhance top mirror reflectivity). Via and a plating steps can then be performed, as well as formation of the AR coating 130 to obtain a finished VCSEL 100 similar to that shown in FIG. 1A.

As indicated above, FIGS. 2A-2C are provided as an example. Other examples may differ from what is described with regard to FIGS. 2A-2C.

FIG. 3 is a diagram illustrating an alternative implementation of the VCSEL 100. In the alternative implementation shown in FIG. 3, the VCSEL does not include the cap layer 120 (e.g., the VCSEL does not include a GaAs cap layer 120 on the AlGaAs grating layer 116). In some implementations, the VCSEL 100 may be formed without the cap layer 120 when an aluminum fraction in the grating layer 116 is sufficiently low such that surface oxidation in air is tolerable. Formation of the VCSEL 100 may be simplified in such an implementation because there is no need to selectively remove the cap layer 120, and wet thermal oxidation may be selectively masked by only a portion of the dielectric layer 122 (e.g., rather than by both the cap layer 120 and the portion of the dielectric layer 122, as illustrated in FIG. 2B).

Notably, in the implementation of the VCSEL 100 shown in FIG. 3, an opening can be formed in the grating layer 116, and the contact layer 124 may be formed in the opening. In this way, contact can be provided to a comparatively lower aluminum content layer (e.g., a GaAs layer below the grating layer 116). Alternatively, a contact may be achieved directly on the higher aluminum content grating layer 116. That is, in some implementations, the contact layer may be formed on the grating layer 116 and contact can be provided through the grating layer 116.

As indicated above, FIG. 3 provided as an example. Other examples may differ from what is described with regard to FIG. 3.

In some implementations, as noted above, an aluminum composition within the grating layer 116 can be designed so as to control an oxidation profile of the grating layer 116. FIGS. 4A and 4B are diagrams illustrating a comparison of oxidation profiles for different gradings of aluminum with the grating layer 116.

In some implementations, the aluminum composition within the grating layer 116 may be uniform across a thickness of the grating layer 116 (i.e., the aluminum content may not vary substantially across the thickness of the grating layer 116). In some implementations, a uniform aluminum composition may cause oxidation rates in the vertical and lateral directions to be the same, and therefore will provide a wider oxidation profile (e.g., wider oxidized regions 1180) in the grating layer 116, as illustrated in FIG. 4A.

Alternatively, the aluminum composition within the grating layer 116 may be graded across the thickness of the grating layer 116. For example, the aluminum content of the grating layer 116 nearer to the bottom of the grating layer 116 may be higher than the aluminum content of the grating layer 116 nearer to the top of the grating layer 116. In such an implementation, oxidation in the lateral direction is reduced, and therefore a narrower oxidation profile (e.g., narrower oxidized regions 1180) are formed.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical-cavity surface-emitting laser (VCSEL), comprising:
a first top mirror structure over a cavity region; and
a grating layer over the first top mirror structure,
wherein the grating layer comprises a plurality of oxidized regions that form a grating structure in the grating layer, the grating structure being associated with polarization of output light emitted by the VCSEL, and
wherein the surface of the grating layer is a planar surface.

2. The VCSEL of claim 1, wherein the grating layer comprises aluminum gallium arsenide (AlGaAs).

3. The VCSEL of claim 1, further comprising a dielectric layer over the grating layer.

4. The VCSEL of claim 3, wherein the VCSEL includes a second top mirror structure over the dielectric layer.

5. The VCSEL of claim 1, wherein the VCSEL includes a cap layer over regions of the grating layer in which the grating structure is not present.

6. The VCSEL of claim 1, wherein the VCSEL includes a contact layer over the grating layer.

7. The VCSEL of claim 1, wherein the VCSEL includes a contact layer under the grating layer.

8. The VCSEL of claim 1, wherein the VCSEL includes a contact layer in an opening in the grating layer.

9. The VCSEL of claim 1, wherein the grating structure has a grating depth and a grating period that are on an order of or lower than a wavelength of the VCSEL.

10. The VCSEL of claim 1, wherein a width of an oxidized region of the plurality of oxidized regions is greater than a depth of the oxidized region.

11. The VCSEL of claim 1, wherein a depth of an oxidized region of the plurality of oxidized regions is in a range from approximately 0.11×λ to approximately 0.26×λ, where λ is a wavelength of the VCSEL.

12. The VCSEL of claim 1, wherein a width of an oxidized region of the plurality of oxidized regions is in a range from approximately 0.10×λ to approximately 0.23×λ, where λ is a wavelength of the VCSEL.

13. The VCSEL of claim 1, wherein an aluminum content of the grating layer is in a range from approximately 50% to approximately 80%.

14. The VCSEL of claim 1, wherein an aluminum composition within the grating layer is uniform across a thickness of the grating layer.

15. The VCSEL of claim 1, wherein an aluminum composition within the grating layer is graded across a thickness of the grating layer.

16. A vertical-cavity surface-emitting laser (VCSEL), comprising:
a mirror structure over a cavity region; and
a grating layer over the mirror structure,
wherein the grating layer comprises a plurality of oxidized regions that define a grating structure, and
wherein a top surface of the grating layer is substantially planar.

17. The VCSEL of claim 16, wherein the VCSEL includes a second top mirror structure over the dielectric layer.

18. The VCSEL of claim 16, wherein the grating structure has a grating depth and a grating period that are on an order of or lower than a wavelength of the VCSEL.

19. A vertical-cavity surface-emitting laser (VCSEL), comprising:
a first top mirror structure over a cavity region; and
a planar grating layer over the first top mirror structure,
wherein the planar grating layer comprises a plurality of oxidized regions that form a grating structure within the grating layer, and
wherein the grating structure is associated with increasing reflectivity on a side of the VCSEL that includes the first top mirror structure.

20. The VCSEL of claim 19, wherein the grating structure has a grating depth and a grating period that are on an order of or lower than a wavelength of the VCSEL.
